(19) United States
(12) Patent Application Publication
(10) Pub. No.: US 2026/0168091 A1
(43) Pub. Date: Jun. 18, 2026

(54) PROCESS CHAMBER IMPROVEMENT

(71) Applicant: Applied Materials, Inc., Santa Clara, CA (US)

(72) Inventor: Ala MORADIAN, Sunnyvale, CA (US)

(21) Appl. No.: 18/979,557

(22) Filed: Dec. 12, 2024

(51) Int. Cl. C23C 16/44; C23C 16/458; C23C 16/52

(52) U.S. Cl. CPC C23C 16/4412; C23C 16/4408; C23C 16/4583; C23C 16/52

(57) ABSTRACT

A processing system is provided including a process chamber that includes: a chamber body disposed around an interior volume; a substrate support in the interior volume; a gas inlet channel assembly including a first gas inlet channel and a second gas inlet channel. Each gas inlet channel is coupled with the interior volume, and each gas inlet channel is positioned at a different angular location around the substrate support. The process chamber further includes an exhaust inlet channel assembly including a first exhaust inlet channel and a second exhaust inlet channel. Each exhaust inlet channel is coupled with the interior volume. Each exhaust inlet channel is positioned at a different angular location around the substrate support. At least a portion of the first exhaust inlet channel directly underlies the first gas inlet channel. At least a portion of the second exhaust inlet channel directly underlies the second gas inlet channel.

### BACKGROUND

### Field

Embodiments of the present disclosure generally relate to improved process chambers for processing of substrates, such as semiconductor substrates. More particularly, the improvements relate to gas delivery features of the process chambers that improve the uniformity of the process performed on the substrate, such as a deposition.

### Description of the Related Art

Substrates, such as semiconductor substrates, are positioned on substrate supports in process chambers during processes (e.g., depositions) performed on the substrate. Gas is typically provided to process chambers from (1) above the substrate support using a showerhead or (2) from one side of the substrate support using a cross-flow configuration where the gas is exhausted on the opposing side of the substrate support. Some processes, such as epitaxy, have obtained better results using the cross-flow configuration for the gas flow through the interior of the chamber. When gas is delivered to the process chamber on one side and exhausted on the other side using the cross-flow configuration, the substrate support is rotated to ensure that each portion of the substrate is exposed to substantially the same amount of fresh precursor gas (i.e., when the substrate is rotated to locations closest to the gas inlet) and mixtures with the highest concentration of byproducts (i.e., when the substrate is rotated to locations closest to the gas exhaust).

Although rotating the substrate support improves uniformity results, such as deposition thickness uniformity, non-uniformities persist. Thus, there is an ongoing need to improve process uniformity for processes performed in process chambers, such as depositions processes.

### SUMMARY

The present disclosure generally relates to equipment and related methods for improving the uniformity of processes performed on substrates in process chambers, such as epitaxial depositions.

In one embodiment, a processing system is provided comprising: a process chamber comprising: a chamber body disposed around an interior volume; a substrate support in the interior volume; a gas inlet channel assembly comprising a first gas inlet channel and a second gas inlet channel, wherein each gas inlet channel is coupled with the interior volume, and each gas inlet channel is positioned at a different angular location around the substrate support; and an exhaust inlet channel assembly comprising a first exhaust inlet channel and a second exhaust inlet channel, wherein each exhaust inlet channel is coupled with the interior volume, each exhaust inlet channel is positioned at a different angular location around the substrate support, at least a portion of the first exhaust inlet channel directly underlies the first gas inlet channel, and at least a portion of the second exhaust inlet channel directly underlies the second gas inlet channel; and a controller configured to: provide gas to the interior volume through the first gas inlet channel during a first time period without providing gas to the interior volume through the second gas inlet channel during the first time period; and exhaust gas from the interior volume through the second exhaust inlet channel during the first time period without exhausting gas through the first exhaust inlet channel during the first time period.

In another embodiment, a method of processing a substrate is provided comprising: positioning a substrate on a substrate support in an interior volume of a process chamber, the process chamber comprising: a chamber body disposed around the interior volume; and a gas inlet channel assembly comprising a first gas inlet channel and a second gas inlet channel, wherein each gas inlet channel of the gas inlet channel assembly is coupled with the interior volume, and each gas inlet channel is positioned at a different angular location around the substrate support; providing gas to the interior volume through the first gas inlet channel to direct the gas along a first flow path over the substrate during a first time period without providing gas to the interior volume through the second gas inlet channel during the first time period, and providing gas to the interior volume through the second gas inlet channel to direct the gas along a second flow path over the substrate during a second time period without providing gas to the interior volume through the first gas inlet channel during the second time period.

In another embodiment, a method of processing a substrate is provided comprising: positioning a substrate on a substrate support in an interior volume of a process chamber, the process chamber comprising: a chamber body disposed around the interior volume; and an exhaust inlet channel assembly comprising a first exhaust inlet channel, a second exhaust inlet channel, and a third exhaust inlet channel wherein each exhaust inlet channel is coupled with the interior volume, and each exhaust inlet channel is positioned at a different angular location around the substrate support; providing gas to the interior volume of the process chamber; exhausting gas from the interior volume through the second exhaust inlet channel and the third exhaust inlet channel to direct the gas along a first flow path over the substrate during a first time period without exhausting gas from the interior volume through the first exhaust inlet channel during the first time period, and exhausting gas from the interior volume through the first exhaust inlet channel and the third exhaust inlet channel to direct the gas along a second flow path over the substrate during a second time period without exhausting gas from the interior volume through the second exhaust inlet channel during the second time period.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a cross-sectional view of a processing system, according to one embodiment.

FIG. 2A is a top schematic view of the components of the processing system, such as the gas inlet channel assembly, that are configured to provide gas to the interior volume of the process chamber, according to one embodiment.

FIG. 2B is a top schematic view of the components of the processing system, such as the exhaust inlet channel assembly, that are configured to exhaust gas from the interior volume of the process chamber, according to one embodiment.

FIG. 3 is a process flow diagram of a method for processing a substrate in the processing system from FIG. 1, according to one embodiment.

FIGS. 4A-4C show how gas is directed over the substrate during different portions of the method from FIG. 3, according to one embodiment.

FIG. 5A is a top schematic view of components of an alternative processing system that are configured to provide gas to the interior volume of a process chamber, according to one embodiment.

FIG. 5B is a top schematic view of components of the alternative processing system that are configured to exhaust gas from the interior volume of the process chamber, according to one embodiment.

FIG. 6A is a top schematic view of components of an alternative processing system that are configured to provide gas to the interior volume of a process chamber, according to one embodiment.

FIG. 6B is a top schematic view of components of the alternative processing system that are configured to exhaust gas from the interior volume of the process chamber, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment and related methods for improving the uniformity of processes performed on substrates in process chambers, such as epitaxial depositions. The improvements disclosed herein are obtained by directing gases into the interior volume of the process chamber from a plurality of locations disposed around the substrate support while exhausting gases from a plurality of locations (e.g., opposing locations) around the substrate support. The locations for the supplying of gases as well as the locations for exhausting the gases change over the duration of the process, so that gases are provided from substantially all of the areas disposed around the substrate support and gases are exhausted from substantially all of the areas disposed around the substrate support. Thus, the equipment disclosed herein uses a cross-flow configuration for the gas flow in which the path of the gas flow over the substrate changes over time. The changing of this gas flow path over time creates an effect that is similar to rotating the substrate when a cross-flow configuration using a single gas flow path is used for a process, such as in a conventional epitaxy chamber.

Furthermore, because the substrate is not rotated, improvements in process uniformity (e.g., deposition thickness uniformity) can be achieved. These improvements in process uniformity result from the elimination of vortices and other undesirable gas flow patterns over the substrate that can be caused by a rotating substrate and substrate support. Thus, by using a plurality of flow paths over the substrate to expose the substrate to gas mixtures that are similar to that which the substrate is exposed during rotation in a conventional process, but without the vortices and other undesirable gas flows, a higher level of process uniformity can be achieved.

Although the following disclosure mainly describes improvements in equipment and methods improving process uniformity (e.g., deposition thickness uniformity) for depositions performed on substrates in an epitaxial deposition chamber, the benefits of this disclosure can also be applied to other deposition chambers (e.g., chemical vapor deposition (CVD) chambers or plasma enhanced CVD chambers) as well as to process chambers configured to perform different processes, such as etching. More generally, the benefits of this disclosure can apply to any process that provides gas to a process chamber in a cross-flow configuration.

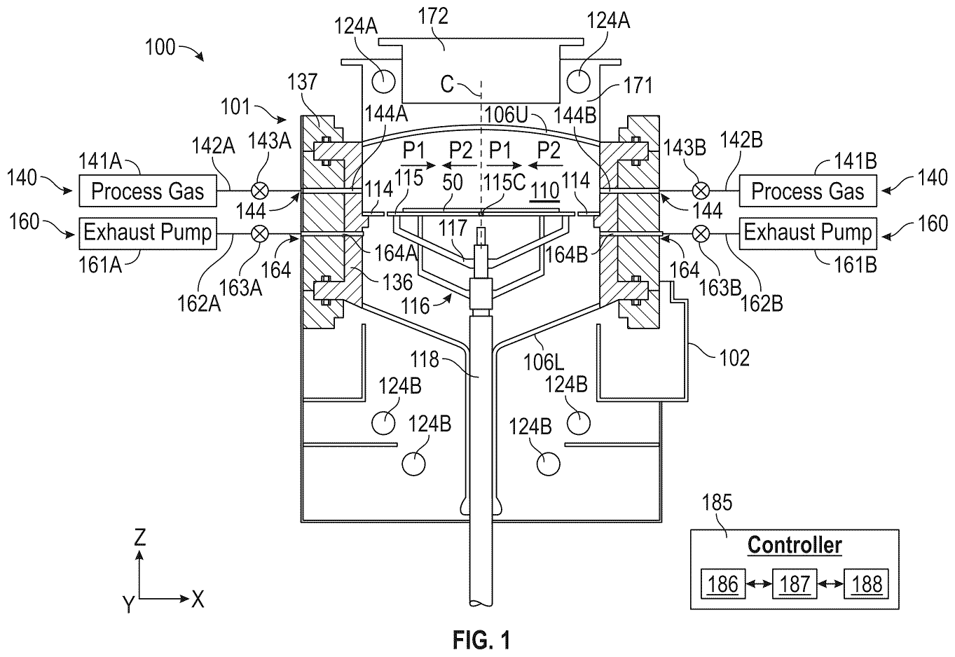

FIG. 1 is a cross-sectional view of a processing system 100, according to one embodiment. The processing system 100 includes a process chamber 101, a gas supply system 140, an exhaust system 160, and a controller 185. A substrate 50 is shown positioned on a substrate support in an interior volume 110 of the process chamber 101. The processing system 100 can be configured to perform epitaxial deposition processes on the substrate 50 in the process chamber 101 as well as other processes, such as cleaning processes. Notably, the substrate support in some embodiments may be configured to not rotate, or the controller 185 can be configured to perform processes, such as epitaxial depositions, without rotating the substrate support in embodiments in which the substrate support is rotatable. The embodiments disclosed herein direct gases over the substrate 50 along various paths that can improve process uniformity in a similar way that rotating the substrate support can achieve when a single gas flow path over a substrate is used.

As described in further detail below, the controller 185 can operate the gas supply system 140 and the exhaust system 160 to change the direction of gas flowing through the interior volume 110 of the process chamber 101 over the substrate 50. For example, the controller 185 can direct process gases through the interior volume 110 of the process chamber 101 along a first path P1 during a first time period, and then direct the process gases through the interior volume 110 of the process chamber 101 along a second path P2 that is different than the first path P1 during a second time period. Although only two gas flow paths P1, P2 are shown, some embodiments can include more gas flow paths, such as five or more gas flow paths or 20 or more gas flow paths. Each different gas flow path exposes different portions of the substrate 50 in the process chamber 101 to different concentrations of fresh process gas and byproducts, so that over the duration of the process, the uniformity of the process being performed on the substrate can be improved when compared to directing the gas over a non-rotating substrate using a single gas flow path for the entire process.

The process chamber 101 includes a chamber body 102. In some embodiments, the chamber body 102 can be made of a process resistant material, such as aluminum or stainless steel, for example 316L stainless steel. The chamber body 102 is disposed around structural components of the process chamber 101, such as an upper window 106U, a lower window 106L, an inner liner 136, and an outer liner 137. In one embodiment, the windows 106U, 106L can each be formed of quartz. The liners 136, 137 can be positioned between the windows 106U, 106L and the chamber body 102 to insulate the windows 106U, 106L from the chamber body 102. The windows 106U, 106L and the liners 136, 137 enclose the interior volume 110 (also referred to as process volume) of the process chamber 101.

The process chamber 101 includes a substrate support assembly 116. The substrate support assembly 116 can include supports 117 and a shaft 118. A susceptor 115 can be positioned on the supports 117. The substrate 50 is positioned on the susceptor 115 during processing, such as during an epitaxial deposition. The susceptor 115 can also generally be referred to as a substrate support.

The process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

The process chamber 101 further includes an outer reflector 171 and an inner reflector 172 positioned over the upper window 106U. The outer reflector 171 can be positioned around the inner reflector 172. In some embodiments, one or more upper lamp modules 124A can be positioned inside the outer reflector 171.

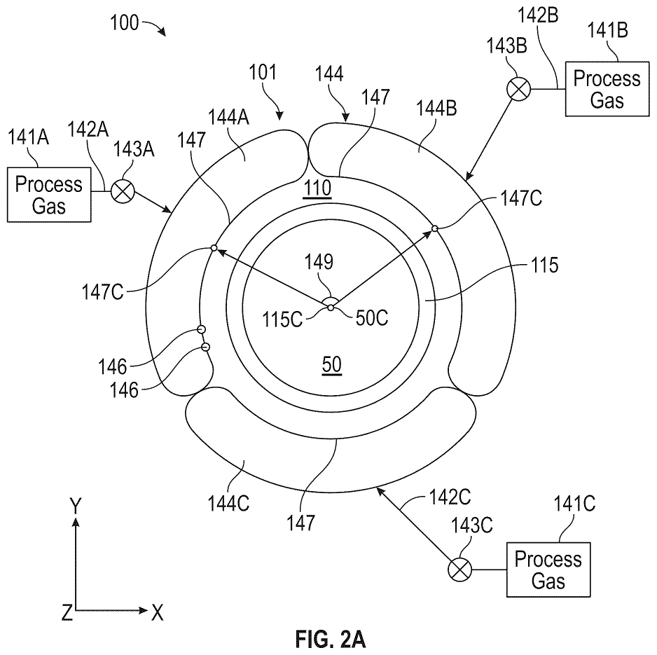

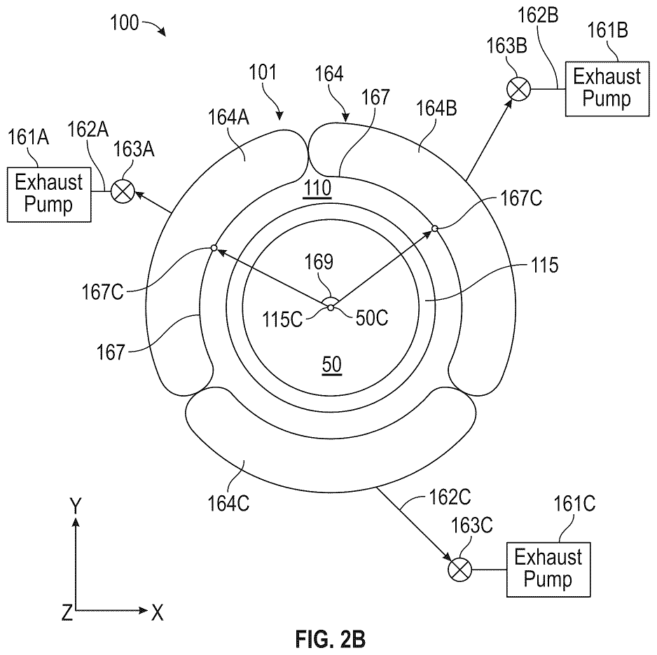

The process chamber 101 can further include a gas inlet channel assembly 144 including a first gas inlet channel 144A and a second gas inlet channel 144B. The gas inlet channels 144A, 144B can extend through the liners 136, 137 to provide a gas flow path into the interior volume 110 for the process gas. In some embodiments, the gas inlet channels 144A, 144B are formed by surfaces of the liners 136, 137. The gas inlet channels 144A, 144B can be positioned at a vertical location above the susceptor 115, so that the process gas is directed from the gas inlet channels 144A, 144B and over the substrate 50 positioned on the susceptor 115. The process chamber 101 can further include a third gas inlet channel 144C (see FIG. 2A) that is not visible in the cross-sectional view of FIG. 1. The gas inlet channels 144A-144C can be positioned at different angular locations relative to a central vertical axis C extending through a center 115C of the susceptor 115.

The gas supply system 140 includes a first process gas source 141A, a first process gas line 142A, and a first process gas valve 143A located on the first process gas line 142A. The first process gas source 141A is fluidly coupled to the first gas inlet channel 144A through the first process gas line 142A. The first process gas valve 143A can be opened and closed to control the flow of process gas from the first process gas source 141A to the first gas inlet channel 144A.

The gas supply system 140 further includes a second process gas source 141B, a second process gas line 142B, and a second process gas valve 143B located on the second process gas line 142B. The second process gas source 141B is fluidly coupled to the second gas inlet channel 144B through the second process gas line 142B. The second process gas valve 143B can be opened and closed to control the flow of process gas from the second process gas source 141B to the second gas inlet channel 144B. In some embodiments, a single process gas source is used for the process gas sources 141A, 141B.

The process chamber 101 can further include an exhaust inlet channel assembly 164 including a first exhaust inlet channel 164A and a second exhaust inlet channel 164B. The exhaust inlet channels 164A, 164B can extend through the liners 136, 137 to provide a gas flow path out of the interior volume 110. In some embodiments, the exhaust inlet channels 164A, 164B are formed by surfaces of the liners 136, 137. In some embodiments, which can be combined with other embodiments, the exhaust inlet channels 164A, 164B can be positioned at a vertical location below the susceptor 115. The process chamber 101 can further include a third exhaust inlet channel 164C (see FIG. 2B) that is not visible in the cross-sectional view of FIG. 1. The exhaust inlet channels 164A-164C can be positioned at different angular locations relative to the central vertical axis C extending through the center 115C of the susceptor 115.

The exhaust system 160 includes a first exhaust pump 161A, a first exhaust line 162A, and a first exhaust valve 163A located on the first exhaust line 162A. The first exhaust pump 161A is fluidly coupled to the first exhaust inlet channel 164A through the first exhaust line 162A. The first exhaust valve 163A and the first exhaust pump 161A can be operated to control the flow of gas from the interior volume 110 through the first exhaust inlet channel 164A and to the first exhaust pump 161A.

The exhaust system 160 further includes a second exhaust pump 161B, a second exhaust line 162B, and a second exhaust valve 163B located on the second exhaust line 162B. The second exhaust pump 161B is fluidly coupled to the second exhaust inlet channel 164B through the second exhaust line 162B. The second exhaust valve 163B and the second exhaust pump 161B can be operated to control the flow of gas from the interior volume 110 through the second exhaust inlet channel 164B and to the second exhaust pump 161B. In some embodiments, a single exhaust pump is used for the exhaust pumps 161A, 161B.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as epitaxial deposition processes and purging processes. During execution of these programs, the controller 185 can communicate to I/O devices through the I/O circuits 188. For example, during execution of these programs and communication through the I/O circuits 188, the controller 185 can control outputs, such as the position of valves to send process gases to the interior volume 110 of the process chamber 101 or to perform purging processes. The memory 186 can further include various operational settings used to control the processing system 100. For example, the settings can include durations for how long the different valves remain open or closed during different depositions and purging processes.

FIG. 2A is a top schematic view of the components of the processing system 100, such as the gas inlet channel assembly 144, that are configured to provide gas to the interior volume 110 of the process chamber 101, according to one embodiment. Most components of the process chamber 101 are omitted in FIG. 2A, so that the spatial relationship between the gas inlet channels 144A-144C and the susceptor 115 can be more clearly illustrated.

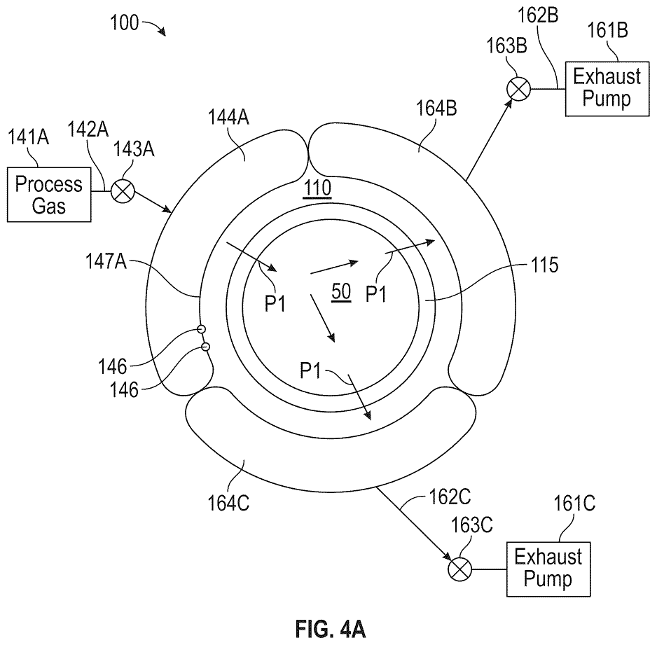

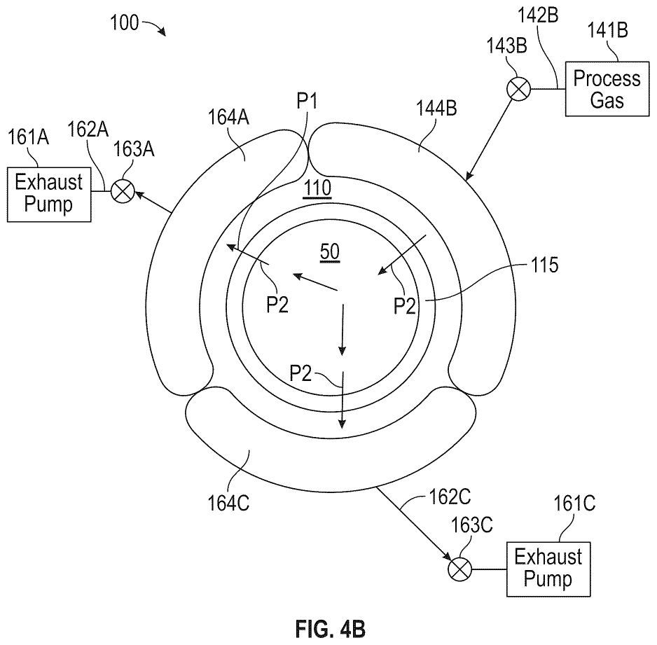

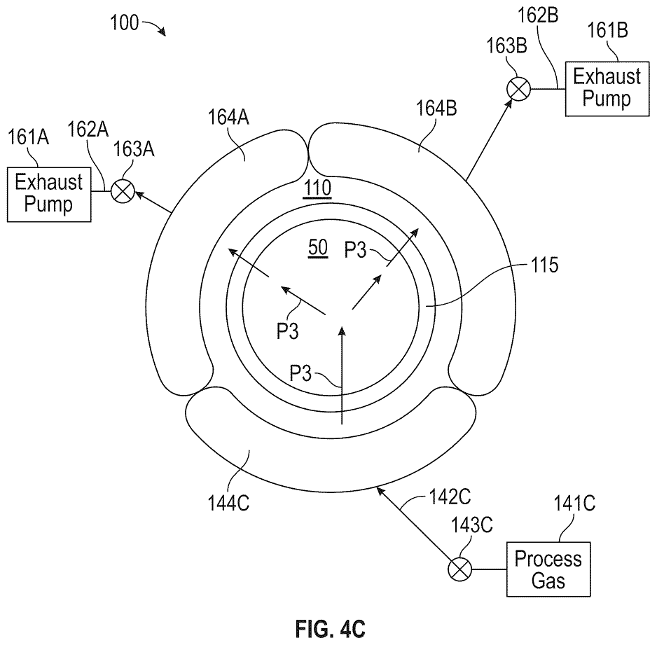

The gas inlet channel assembly 144 includes the first gas inlet channel 144A, the second gas inlet channel 144B, and a third gas inlet channel 144C. Each gas inlet channel 144A-144C is positioned at a different angular location relative to the center 115C of the susceptor 115. Positioning the gas inlet channels 144A-144C at different angular locations allows process gases to be directed over the substrate 50 and the susceptor 115 along different flow paths during different time periods as described in additional detail in reference to FIGS. 4A-4C. Each different flow path exposes different portions of the substrate 50 to different concentrations of fresh process gas and byproducts. When process gases are directed over the substrate using different flow paths, different portions of the substrate 50 can be exposed to similar concentrations of fresh process gas and byproducts when averaged over a time period when all of the flow paths are used. These similar concentrations over time create an effect for balancing the concentrations over the substrate that is similar to the effect caused by rotation of the substrate but without the problems (e.g., vortices) caused by rotation described above.

Each gas inlet channel 144A-144C can include a corresponding inner surface 147. Each inner surface 147 can be configured to direct gas into the interior volume 110 along all or substantially all of the corresponding inner surface 147. For example, in one embodiment, which can be combined with other embodiments, each inner surface 147 includes a plurality of orifices 146 that are configured to direct process gases over the substrate 50 and susceptor 115. These orifices 146 can be spaced apart (e.g., regularly spaced apart) along all of the inner surface 147 for each gas inlet channel 144A-144C. Only two orifices 146 are shown on the gas inlet channel 144A to avoid cluttering the drawing. These orifices 146 can be sized and oriented to have the process gasses delivered into the interior volume 110 with a targeted direction and velocity over the substrate 50 and susceptor 115.

The gas inlet channels 144A-144C can be sized and positioned to not overlap. The gas inlet channels 144A-144C can additionally be sized and positioned, so that there is little (e.g., a few mm) to no separation between the inner surface is 147 of the different gas inlet channels 144A-144C. Each gas inlet channel 144A-144C is positioned at a different angular location relative to the center 115C of the susceptor 115. For example, the angular location of a center 147C of the inner surface 147 of the first gas inlet channel 144A is offset from the angular location of a center 147C of the second gas inlet channel 144B by an angle 149. In this embodiment with three gas inlet channels 144A-144C, the angle 149 is 120°. Thus, each gas inlet channel 144A-144C directs gas into a different third of the interior volume 110. In some embodiments, which can be combined with other embodiments, the angle 149 can be from about 120° to about 15°, such as about 45°. In still other embodiments, the angle 149 can even be as low as 1° or even lower, so that in such an embodiment there would be 360 independently controlled gas inlet channels for all 360° around the susceptor 115.

FIG. 2B is a top schematic view of the components of the processing system 100, such as the exhaust inlet channel assembly 164, that are configured to exhaust gas from the interior volume 110 of the process chamber 101, according to one embodiment. Most components of the process chamber 101 are omitted in FIG. 2B, so that the spatial relationship between the exhaust inlet channels 164A-164C and the susceptor 115 can be more clearly illustrated.

The process chamber 101 includes a first exhaust inlet channel 164A, a second exhaust inlet channel 164B, and a third exhaust inlet channel 164C. Each exhaust inlet channel 164A-164C is positioned at a different angular location relative to the center 115C of the susceptor 115. Positioning the exhaust inlet channels 164A-164C at different angular locations allows gases in the interior volume 110 to be exhausted from different locations in the interior volume 110 at different times. The different locations of the exhaust inlet channels 164A-164C also assists in directing the gases along the different flow paths during different time periods as described in more detail below in reference to FIGS. 4A-4C. Generally, at least one of the exhaust inlet channels 164A-164C is not actively exhausting gas during any given time period during processing of the substrate 50. The one or more exhaust inlet channels 164A-164C that is not active is switched during the processing of the substrate 50, so that the flow paths of gases over the substrate 50 can be changed over the duration of processing of the substrate 50. The angular location of the one or more exhaust inlet channels 164A-164C that are active can be offset from the active gas inlet channel 144A-144C by the angle 149 (e.g., 120°) described above.

In some embodiments, which can be combined with other embodiments, at least a portion of each exhaust inlet channel 164A-164C directly underlies (i.e., share the same positions in respective XY planes) a corresponding gas inlet channel 144A-144C. For example, with reference to FIG. 2A and FIG. 2B, the first exhaust inlet channel 164A can directly underlie the first gas inlet channel 144A with each inlet channel 144A, 164A spanning the same angular locations relative to the center 115C of the susceptor 115. Generally, when a gas inlet channel 144A-144C is actively being used during the processing of a substrate 50, the directly underlying exhaust inlet channel 164A-164C is inactive, so that fresh process gas is not exhausted from the interior volume 110 before reaching the regions of the interior volume 110 over the substrate 50.

Each exhaust inlet channel 164A-164C can include an inner surface 167. The exhaust inlet channels 164A-164C can be sized and positioned to not overlap. The exhaust inlet channels 164A-164C can additionally be sized and positioned, so that there is little (e.g., a few mm) to no separation between the inner surface is 167 of the different exhaust inlet channels 164A-164C. Each exhaust inlet channel 164A-164C is positioned at a different angular location relative to the center 115C of the susceptor 115. For example, the angular location of a center 167C of the inner surface 167 of the first exhaust inlet channel 164A is offset from the angular location of a center 167C of the second exhaust inlet channel 164B by an angle 169. In this embodiment, the angle 169 is 120°. Thus, each exhaust inlet channel 164A-164C exhausts gas from a different third of the interior volume 110. In some embodiments, which can be combined with other embodiments, the angle 169 can be from about 120° to about 15°, such as about 45°. In still other embodiments, the angle 169 can even be as low as 1° or even lower, so that in such an embodiment there would be 360 independently controlled exhaust inlet channels for all 360° around the susceptor 115.

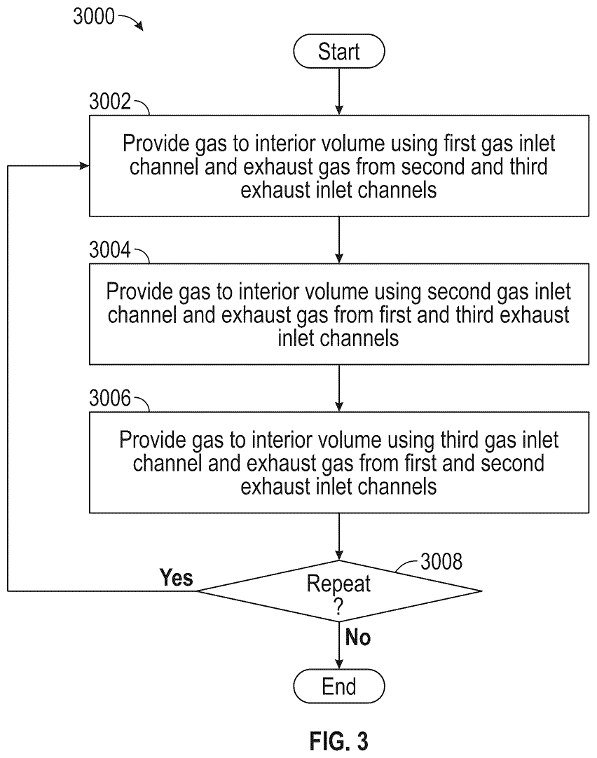

FIG. 3 is a process flow diagram of a method 3000 for processing a substrate 50 in the processing system 100 from FIG. 1, according to one embodiment. FIGS. 4A-4C show how gas is directed over the substrate 50 during different portions of the method 3000 from FIG. 3, according to one embodiment. Notably, FIGS. 4A-4C use top views and only show the gas inlet channels 144A-144C and exhaust inlet channels 164A-164C that are actively being used during a given time period while omitting the gas inlet channels 144A-144C and exhaust inlet channels 164A-164C that are not actively being used. The method 3000 can be executed by the controller 185.

The method 3000 begins at block 3002. Block 3002 is executed during a first time period. At block 3002 and with reference to FIG. 4A, a substrate 50 is positioned on the susceptor 115 and process gas is directed along a first flow path P1 over the substrate 50 and susceptor 115. During block 3002, process gas is provided to the interior volume 110 through the first gas inlet channel 144A by opening of the first process gas valve 143A. Additionally, during block 3002 gas is exhausted from the interior volume 110 through the second exhaust inlet channel 164B by the second exhaust pump 161B and through the third exhaust inlet channel 164C by the third exhaust pump 161C when the second exhaust valve 163B and the third exhaust valve 163C are each opened. Although not shown in FIG. 4A, the second process gas valve 143B and the third process gas valve 143C are closed during block 3002. Additionally, the first exhaust pump 161A (not shown) is not activated during block 3002 and the first exhaust valve 163A is closed, so that block 3002 is executed without exhausting gas through the first exhaust inlet channel 164A.

At block 3004 and with reference to FIG. 4B, process gas is directed along a second flow path P2 over the substrate 50 and susceptor 115. Block 3004 is executed during a second time period. During block 3004, process gas is provided to the interior volume 110 through the second gas inlet channel 144B by opening of the second process gas valve 143B. Additionally, during block 3004 gas is exhausted from the interior volume 110 through the first exhaust inlet channel 164A by the first exhaust pump 161A and through the third exhaust inlet channel 164C by the third exhaust pump 161C when the first exhaust valve 163A and the third exhaust valve 163C are each opened. Although not shown in FIG. 4B, the first process gas valve 143A and the third process gas valve 143C are closed during block 3004. Additionally, the second exhaust pump 161B (not shown) is not activated during block 3004 and the second exhaust valve 163B is closed, so that block 3004 is executed without exhausting gas through the second exhaust inlet channel 164B.

At block 3006 and with reference to FIG. 4C, process gas is directed along a third flow path P3 over the substrate 50 and susceptor 115. Block 3006 is executed during a third time period. During block 3006, process gas is provided to the interior volume 110 through the third gas inlet channel 144C by opening of the third process gas valve 143C. Additionally, during block 3006, gas is exhausted from the interior volume 110 through the first exhaust inlet channel 164A by the first exhaust pump 161A and through the second exhaust inlet channel 164B by the second exhaust pump 161B when the first exhaust valve 163A and the second exhaust valve 163B are each opened. Although not shown in FIG. 4C, the first process gas valve 143A and the second process gas valve 143B are closed during block 3006. Additionally, the third exhaust pump 161C (not shown) is not activated during block 3006 and the third exhaust valve 163C is closed, so that block 3006 is executed without exhausting gas through the third exhaust inlet channel 164C.

At block 3008, a decision is made to repeat blocks 3002-3006. The blocks 3002-3006 can be repeated any number of times. In some embodiments, which can be combined with other embodiments, each block 3002, 3004, 3006 can be executed for duration from about 0.1 second to about ten seconds, such as about 0.5 seconds. Although only three gas inlet channels 144A-144C are shown, other embodiments can use additional gas inlet channels and additional exhaust inlet channels that can each be independently controlled. The greater the number of independently controlled gas inlet channels and independently controlled exhaust inlet channels that are used, the more the average gas concentrations over the substrate can resemble the corresponding gas concentrations over a rotating substrate when a single gas flow path is used, such as in a conventional epitaxy process chamber. Used herein, an independently controlled gas inlet channel or independently controlled exhaust inlet channel refers to the gas inlet channel or an exhaust inlet channel which has a device, such as a dedicated valve or pump, to independently control the flow of gas through that corresponding inlet channel.

Furthermore, although two independently controlled gas inlet channels and two independently controlled exhaust inlet channels can significantly improve the uniformity of the concentrations of fresh process gas and byproducts over different portions of the substrate, using at least three independently controlled gas inlet channels and at least three independently controlled exhaust inlet channels can generate concentration profiles of fresh process gas and byproducts that more closely resemble the concentrations that a rotating substrate would be exposed to in a conventional process chamber using a single gas flow path over the substrate, such as a conventional epitaxy chamber.

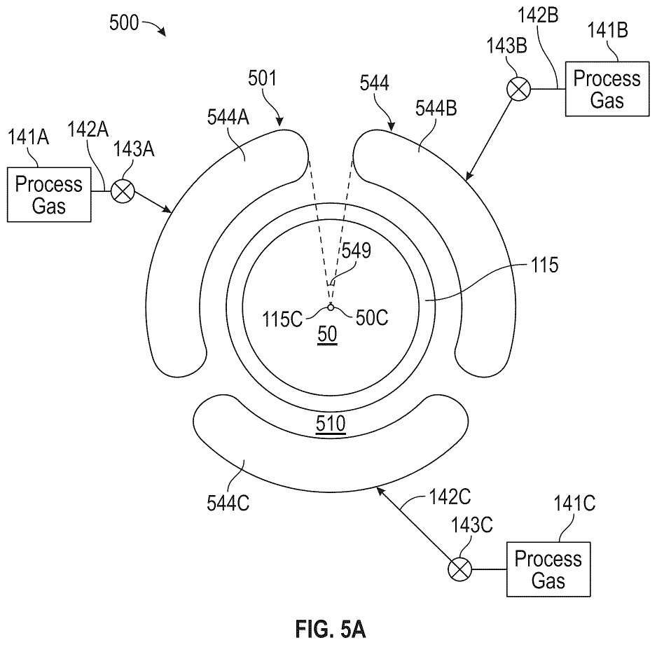

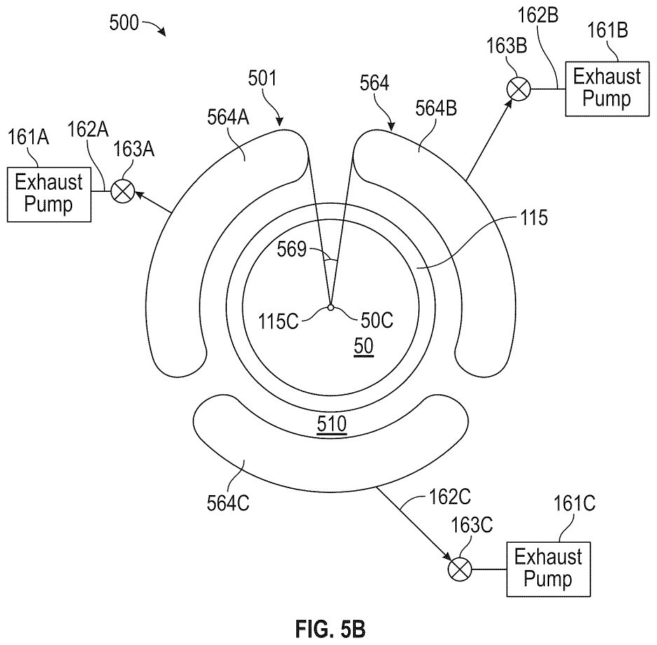

FIG. 5A is a top schematic view of components of an alternative processing system 500 that are configured to provide gas to the interior volume 510 of a process chamber 501, according to one embodiment. With additional reference to FIGS. 1 and 2A, the process chamber 501 is the same as the process chamber 101 described above except that the gas inlet channel assembly 144 is replaced with a gas inlet channel assembly 544 and the exhaust inlet channel assembly 164 is replaced with an exhaust inlet channel assembly 564 as described below in reference to FIG. 5B. Like FIG. 2A described above, most components of the process chamber 501 are omitted in FIG. 5A, so that the spatial relationship between the gas inlet channel assembly 544 and the susceptor 115 can be more clearly illustrated.

The gas inlet channel assembly 544 includes a first gas inlet channel 544A, a second gas inlet channel 544B, and a third gas inlet channel 544C. Each gas inlet channel 544A-544C is positioned at a different angular location relative to the center 115C of the susceptor 115. Each gas inlet channel 544A-544C can have an angular location relative to the center 115C of the susceptor 115 that is separated from the other gas inlet channels by angle 549 that is from about 1 degree to about 45 degrees, such as about 30 degrees. This angular separation can simplify the fabrication, installation, and maintenance of the separate gas inlet channels.

FIG. 5B is a top schematic view of components of the alternative processing system 500 that are configured to exhaust gas from the interior volume 510 of the process chamber 501, according to one embodiment. With additional reference to FIGS. 1 and 2B, the process chamber 501 is the same as the process chamber 101 described above except that the gas inlet channel assembly 144 is replaced with the gas inlet channel assembly 544 (see FIG. 5A) and the exhaust inlet channel assembly 164 is replaced with the exhaust inlet channel assembly 564. Like FIG. 2B described above, most components of the process chamber 501 are omitted in FIG. 5B, so that the spatial relationship between the exhaust inlet channel assembly 564 and the susceptor 115 can be more clearly illustrated.

The exhaust inlet channel assembly 564 includes a first exhaust inlet channel 564A, a second exhaust inlet channel 564B, and a third exhaust inlet channel 564C. Each exhaust inlet channel 564A-564C is positioned at a different angular location relative to the center 115C of the susceptor 115. Each exhaust inlet channel 564A-564C can have an angular location relative to the center 115C of the susceptor 115 that is separated from the other exhaust inlet channels by an angle 569 that is from about 1 degree to about 45 degrees, such as about 30 degrees. This angular separation can simplify the fabrication, installation, and maintenance of the separate exhaust inlet channels.

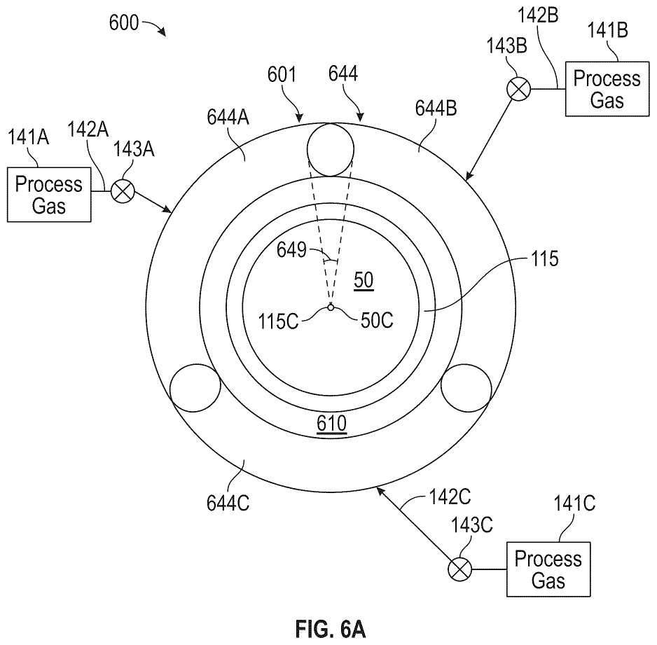

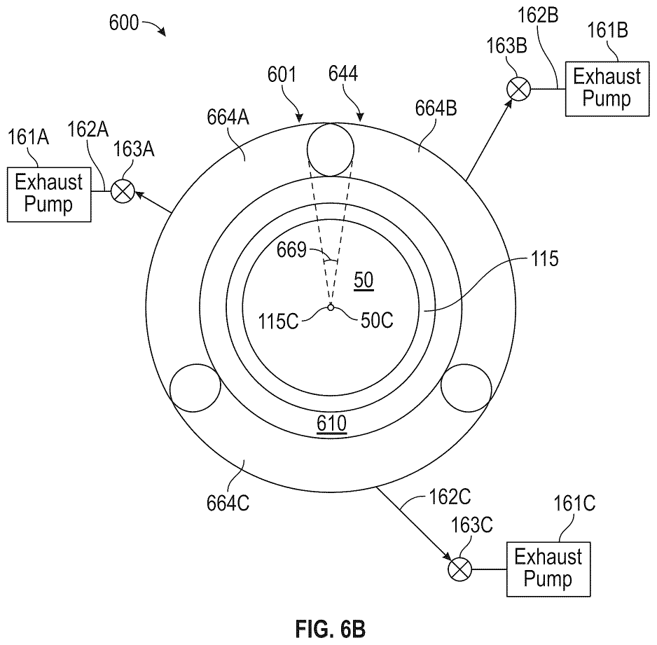

FIG. 6A is a top schematic view of components of an alternative processing system 600 that are configured to provide gas to the interior volume 610 of a process chamber 601, according to one embodiment. With additional reference to FIGS. 1 and 2A, the process chamber 601 is the same as the process chamber 101 described above except that the gas inlet channel assembly 144 is replaced with a gas inlet channel assembly 644 and the exhaust inlet channel assembly 164 is replaced with an exhaust inlet channel assembly 664 as described below in reference to FIG. 6B. Like FIG. 2A described above, most components of the process chamber 601 are omitted in FIG. 6A, so that the spatial relationship between the gas inlet channel assembly 644 and the susceptor 115 can be more clearly illustrated.

The gas inlet channel assembly 644 includes a first gas inlet channel 644A, a second gas inlet channel 644B, and a third gas inlet channel 644C. Each gas inlet channel 644A-644C is positioned at a different angular location relative to the center 115C of the susceptor 115. Each gas inlet channel 644A-644C can have an angular location relative to the center 115C of the susceptor 115 that overlaps the next closest gas inlet channel 644A-644C by an angle 649 that is from about 1 degree to about 45 degrees, such as about 30 degrees. This angular overlap can assist in providing more efficient distribution of gaseous precursors and improve tuning for the gas flows, particularly for high pressure operations, such as operations performed at pressures from about 150 Torr to about 760 Torr.

FIG. 6B is a top schematic view of components of the alternative processing system 600 that are configured to exhaust gas from the interior volume 610 of the process chamber 601, according to one embodiment. With additional reference to FIGS. 1 and 2B, the process chamber 601 is the same as the process chamber 101 described above except that the gas inlet channel assembly 144 is replaced with a gas inlet channel assembly 644 (see FIG. 6A) and the exhaust inlet channel assembly 664 is replaced with an exhaust inlet channel assembly 664. Like FIG. 2B described above, most components of the process chamber 601 are omitted in FIG. 6B, so that the spatial relationship between the exhaust inlet channel assembly 664 and the susceptor 115 can be more clearly illustrated.

The exhaust inlet channel assembly 664 includes a first exhaust inlet channel 664A, a second exhaust inlet channel 664B, and a third exhaust inlet channel 664C. Each exhaust inlet channel 664A-664C is positioned at a different angular location relative to the center 115C of the susceptor 115. Each exhaust inlet channel 664A-664C can have an angular location relative to the center 115C of the susceptor 115 that overlaps the next closest gas inlet channel 644A-644C by an angle 669 that is from about 1 degree to about 45 degrees, such as about 30 degrees. This angular overlap can assist in providing more efficient distribution of gaseous precursors and improve tuning for the gas flows, particularly for high pressure operations, such as operations performed at pressures from about 150 Torr to about 760 Torr.

While the foregoing is directed to embodiments of the present disclosure, other and further embodiments of the disclosure may be devised without departing from the basic scope thereof, and the scope thereof is determined by the claims that follow.

1. A processing system comprising:
a process chamber comprising:
a chamber body disposed around an interior volume;
a substrate support in the interior volume;
a gas inlet channel assembly comprising a first gas inlet channel and a second gas inlet channel, wherein each gas inlet channel is coupled with the interior volume, and each gas inlet channel is positioned at a different angular location around the substrate support; and
an exhaust inlet channel assembly comprising a first exhaust inlet channel and a second exhaust inlet channel, wherein each exhaust inlet channel is coupled with the interior volume, each exhaust inlet channel is positioned at a different angular location around the substrate support, at least a portion of the first exhaust inlet channel directly underlies the first gas inlet channel, and at least a portion of the second exhaust inlet channel directly underlies the second gas inlet channel; and
a controller configured to:
provide gas to the interior volume through the first gas inlet channel during a first time period without providing gas to the interior volume through the second gas inlet channel during the first time period; and
exhaust gas from the interior volume through the second exhaust inlet channel during the first time period without exhausting gas through the first exhaust inlet channel during the first time period.

2. The processing system of claim 1, wherein
the gas inlet channel assembly further comprises a third gas inlet channel,
the exhaust inlet channel assembly further comprises a third exhaust inlet channel, and
at least a portion of the third exhaust inlet channel directly underlies the third gas inlet channel.

3. The processing system of claim 2, wherein an angular location of a center of the first gas inlet channel is offset from angular location of the second gas inlet channel by an angle from about 15 degrees to about 120 degrees.

4. The processing system of claim 2, wherein an angular location of a center of the first exhaust inlet channel is offset from angular location of the second exhaust inlet channel by an angle from about 15 degrees to about 120 degrees.

5. The processing system of claim 2, wherein the controller is further configured to
provide gas to the interior volume through the first gas inlet channel during the first time period without providing gas to the interior volume through the second gas inlet channel during the first time period; and
exhaust gas from the interior volume through the third exhaust inlet channel during the first time period.

6. The processing system of claim 5, wherein the controller is further configured to:
provide gas to the interior volume through the second gas inlet channel during a second time period without providing gas to the interior volume through the first gas inlet channel or the third gas inlet channel during the second time period; and
exhaust gas from the interior volume through the first exhaust inlet channel and the third exhaust inlet channel during the second time period without exhausting gas through the second exhaust inlet channel during the second time period.

7. The processing system of claim 6, wherein the controller is further configured to:
provide gas to the interior volume through the third gas inlet channel during a third time period without providing gas to the interior volume through the first gas inlet channel or the second gas inlet channel during the third time period; and
exhaust gas from the interior volume through the first exhaust inlet channel and the second exhaust inlet channel during the third time period without exhausting gas through the third exhaust inlet channel during the third time period.

8. The processing system of claim 7, wherein the controller is configured to repeat the operations performed during the first time period, the second time period, and the third time period.

9. The processing system of claim 1, wherein the exhaust inlet channel assembly is positioned below the substrate support.

10. A method of processing a substrate comprising:
positioning a substrate on a substrate support in an interior volume of a process chamber, the process chamber comprising:
a chamber body disposed around the interior volume; and
a gas inlet channel assembly comprising a first gas inlet channel and a second gas inlet channel, wherein each gas inlet channel of the gas inlet channel assembly is coupled with the interior volume, and each gas inlet channel is positioned at a different angular location around the substrate support;
providing gas to the interior volume through the first gas inlet channel to direct the gas along a first flow path over the substrate during a first time period without providing gas to the interior volume through the second gas inlet channel during the first time period, and
providing gas to the interior volume through the second gas inlet channel to direct the gas along a second flow path over the substrate during a second time period without providing gas to the interior volume through the first gas inlet channel during the second time period.

11. The method of claim 10, wherein the process chamber further comprises an exhaust inlet channel assembly comprising a first exhaust inlet channel and a second exhaust inlet channel, wherein each exhaust inlet channel is coupled with the interior volume, each exhaust inlet channel is positioned at a different angular location around the substrate support, at least a portion of the first exhaust inlet channel directly underlies the first gas inlet channel, and at least a portion of the second exhaust inlet channel directly underlies the second gas inlet channel.

12. The method of claim 11, further comprising exhausting gas from the interior volume through the second exhaust inlet channel during the first time period without exhausting gas from the interior volume through the first exhaust inlet channel during the first time period.

13. The method of claim 12, further comprising exhausting gas from the interior volume through the first exhaust inlet channel during the second time period without exhausting gas from the interior volume through the second exhaust inlet channel during the second time period.

14. The method of claim 10, wherein the gas inlet channel assembly further comprises a third gas inlet channel.

15. The method of claim 14, further comprising providing gas to the interior volume through the third gas inlet channel to direct the gas along a third flow path over the substrate during a third time period without providing gas to the interior volume through the first gas inlet channel or the second gas inlet channel during the third time period.

16. A method of processing a substrate comprising:
positioning a substrate on a substrate support in an interior volume of a process chamber, the process chamber comprising:
a chamber body disposed around the interior volume; and
an exhaust inlet channel assembly comprising a first exhaust inlet channel,
a second exhaust inlet channel, and a third exhaust inlet channel wherein each exhaust inlet channel is coupled with the interior volume, and each exhaust inlet channel is positioned at a different angular location around the substrate support;
providing gas to the interior volume of the process chamber;
exhausting gas from the interior volume through the second exhaust inlet channel and the third exhaust inlet channel to direct the gas along a first flow path over the substrate during a first time period without exhausting gas from the interior volume through the first exhaust inlet channel during the first time period, and
exhausting gas from the interior volume through the first exhaust inlet channel and the third exhaust inlet channel to direct the gas along a second flow path over the substrate during a second time period without exhausting gas from the interior volume through the second exhaust inlet channel during the second time period.

17. The method of claim 16, further comprising exhausting gas from the interior volume through the first exhaust inlet channel and the second exhaust inlet channel to direct the gas along a third flow path over the substrate during a third time period without exhausting gas from the interior volume through the third exhaust inlet channel during the third time period.

18. The method of claim 17, further comprising repeating the operations performed during the first time period, the second time period, and the third time period.

19. The method of claim 17, wherein the process chamber further comprises a gas inlet channel assembly comprising a first gas inlet channel, a second gas inlet channel, and a third gas inlet channel, wherein the first exhaust inlet channel directly underlies the first gas inlet channel, the second exhaust inlet channel directly underlies the second gas inlet channel, and the third exhaust inlet channel directly underlies the third gas inlet channel.

20. The method of claim 19, wherein gas is provided to the interior volume through the first gas inlet channel during the first time period, through the second gas inlet channel during the second time period, and through the third gas inlet channel during the third time period.
